(19) United States
(12) Patent Application Publication
(10) Pub. No.: US 2026/0349009 A1
(43) Pub. Date: Nov. 5, 2026

(54) CURRENT MEASUREMENT METHODS FOR HCC CONVERTER VALVE

(71) Applicants: State Grid Henan Electric Power Research Institute, Zhengzhou, Henan (CN); State Grid Henan Electric Power Company, Zhengzhou, Henan (CN); DC Technical Center of State Grid Company of China, Beijing (CN); Tsinghua University, Beijing (CN); Xi'an XD Power System Co., Ltd., Xi'an, Shaanxi (CN); Xi'an Peri Power Semiconductor Conversion Technology Co., Ltd., Xi'an, Shaanxi (CN)

(72) Inventors: Degui YAO, Zhengzhou (CN); Jiatao ZHANG, Zhengzhou (CN); Chaofeng ZHANG, Zhengzhou (CN); Jiaxin WU, Zhengzhou (CN); Manling DONG, Zhengzhou (CN); Yiwei LU, Zhengzhou (CN); Sen WANG, Zhengzhou (CN); Chao XIAO, Zhengzhou (CN); Zhenyu WU, Zhengzhou (CN); Weizheng ZHANG, Zhengzhou (CN); Jun ZHANG, Beijing (CN); Lingling XU, Beijing (CN); Xianshan GUO, Beijing (CN); Guohua ZHANG, Beijing (CN); Zhuo WEI, Beijing (CN); Shengfu GAO, Beijing (CN); Rong ZENG, Beijing (CN); Zhanqing YU, Beijing (CN); Yantao LOU, Xi'an (CN); Jiangping WANG, Xi'an (CN); Lei ZHANG, Xi'an (CN); Fengying WANG, Xi'an (CN)

(73) Assignees: State Grid Henan Electric Power Research Institute, Zhengzhou, Henan (CN); State Grid Henan Electric Power Company, Zhengzhou, Henan (CN); DC Technical Center of State Grid Company of China, Beijing (CN); Tsinghua University, Beijing (CN); Xi'an XD Power System Co., Ltd., Xi'an, Shaanxi (CN); Xi'an Peri Power Semiconductor Conversion Technology Co., Ltd., Xi'an, Shaanxi (CN)

(21) Appl. No.: 19/503,725

(22) PCT Filed: Nov. 13, 2025
(86) PCT No.: PCT/CN2025/134627

§ 371 Date: Jan. 20, 2026

(30) Foreign Application Priority Data
Nov. 29, 2024 (CN) 202411745759.2

(51) Int. Cl. G01R 15/18; G01R 19/165; G01R 31/40; H02H 3/087

(52) U.S. Cl. CPC G01R 15/18; G01R 19/16571; G01R 31/40; H02H 3/087

(57) ABSTRACT

An HCC converter valve current measurement strategy, which includes installing a current transformer acquisition device on each arm of the current transformer configuration topology to measure the converter arm current. Each current transformer acquisition device is simultaneously connected to a valve control device and a polarization control device. The valve control device measures the DC bus current and the AC current on the converter transformer valve side for active shutdown judgment, while the polarization control device simultaneously measures the arm current, DC bus current, and AC current on the converter transformer valve side for valve fault judgment. This strategy meets the current measurement requirements of the composite HCC new high-voltage DC converter, serves as a control strategy criterion and equipment protection criterion, and ensures the normal operation of the converter.

### BACKGROUND

### 1. Technical Field

This disclosure belongs to the technical field of novel HCC high-voltage DC converters, specifically relating to HCC converter valve current measurement strategies.

### 2. Background

With the development of power systems, high-voltage direct current (HVDC) transmission technology has gained popularity due to its advantages in long-distance and large-capacity power transmission. Among them, the traditional Line-commutated converter based high voltage direct current (LCC-HVDC) technology has even more obvious advantages in this regard. However, due to the use of thyristors, a semi-controlled device, commutation failures can occur on the inverter side in LCCs. Continuous commutation failures can lead to DC blockage, causing fluctuations in grid voltage and power. To solve the inherent problem of commutation failure, some scholars have proposed a new turn-off converter topology. The difference between this converter and the traditional Line-commutated converter is that each arm of the converter is composed of a series of turn-off thyristors, as shown in FIG. 6 of the specification, forming a series structure of turn-off devices and thyristors. The turn-off devices include, but are not limited to, gate turn-off thyristors (GTOs) and integrated gate commutated thyristors (IGCTs). To realize the function of this type of switchable converter, it is necessary to collect current for equipment operation control and protection. For example, when the converter is working in inverter mode, if commutation failure occurs, it is necessary to determine the time of commutation failure based on the current criterion in order to prevent commutation failure. If the converter current cannot be accurately measured, the system will experience commutation failure, which is very unstable and unreliable for system operation.

### BRIEF SUMMARY

The purpose of this disclosure is to provide HCC converter valve current measurement strategies to address the problems in the existing technologies. The methods meet the current measurement requirements of the new HCC high-voltage DC converter, and perform control strategy judgment and equipment protection judgment for the device to ensure the normal operation of the converter.

The technical solution of this disclosure is:

A method for measuring current in an HCC converter unit, which comprises the following steps:
setting a current transformer acquisition device on each arm of the current transformer configuration topology to measure the converter arm current;
the current transformer acquisition device is connected to both a valve control device and a polarization control device; the valve control device measures the DC bus current and the AC current on the converter transformer valve side to determine active shutdown; the polarization control device simultaneously measures the bridge arm current, the DC bus current, and the AC current on the converter transformer valve side to determine internal valve faults.

Specifically, the polarization control device includes multiple main control units.

Specifically, the valve control device calculates the bridge arm current value, the inflow current and outflow value of the Y valve and D valve based on the CP signal and the bushing current value.

Specifically, the active shutdown judgment includes: one is that the judgment of normal zero-crossing shutdown of the bridge arm during normal operation; another is that the active shutdown is executed when commutation failure occurs and the bridge arm current does not cross zero.

Specifically, the conditions for judging the valve internal fault include overcurrent in the bridge arm, AC overcurrent on the converter transformer valve side, and DC bus overcurrent.

The beneficial effects of this disclosure are: the method provided by this disclosure equips each bridge arm with a current transformer acquisition device, and the active shutdown strategy also measures the DC bus current and the AC current on the converter transformer valve side. Valve faults also simultaneously measure the bridge arm current, DC bus current, and AC current on the converter transformer valve side.

### BRIEF DESCRIPTION OF THE DRAWINGS

FIG. 1 is a schematic diagram of the current transformer configuration topology of the present disclosure;

FIG. 2 is a schematic diagram of the active shutdown execution conditions;

FIG. 3 is a schematic diagram of the valve internal fault conditions;

FIG. 4 is a schematic diagram of the current measurement points;

FIG. 5 is a schematic diagram of the correspondence between the converter valve bridge arm current, the DAY valve inflow/outflow current, and the bushing current in the valve control device;

FIG. 6 is a schematic diagram of the existing technologies of the shut-off converter topology.

1. IGCT valve mixing assembly; 2. IGCT valve failure status; 3. saturated reactor assembly; 4. composite valve bridge arm; 5. HCC converter unit.

### DETAILED DESCRIPTION OF THE DRAWINGS AND THE PRESENTLY PREFERRED EMBODIMENTS

The technical solution of the present disclosure will now be described in detail with reference to the accompanying drawings and specific embodiments.

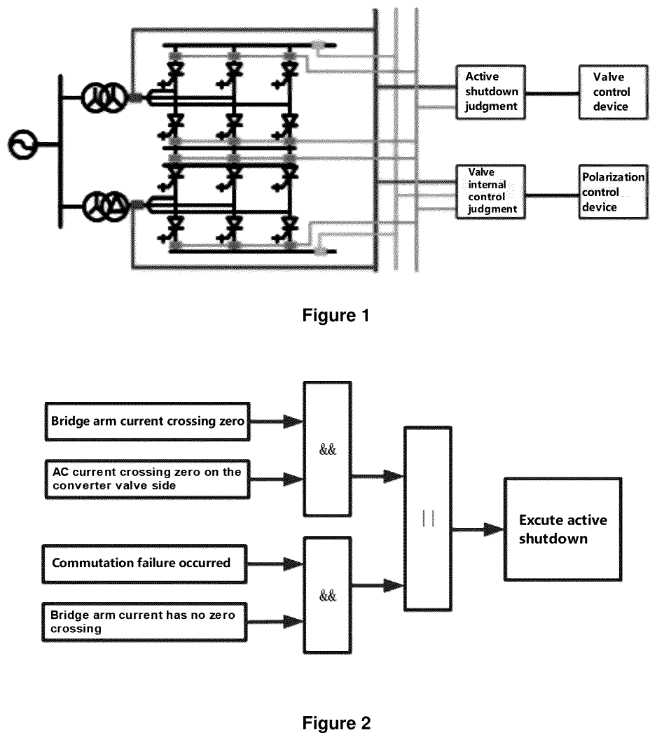

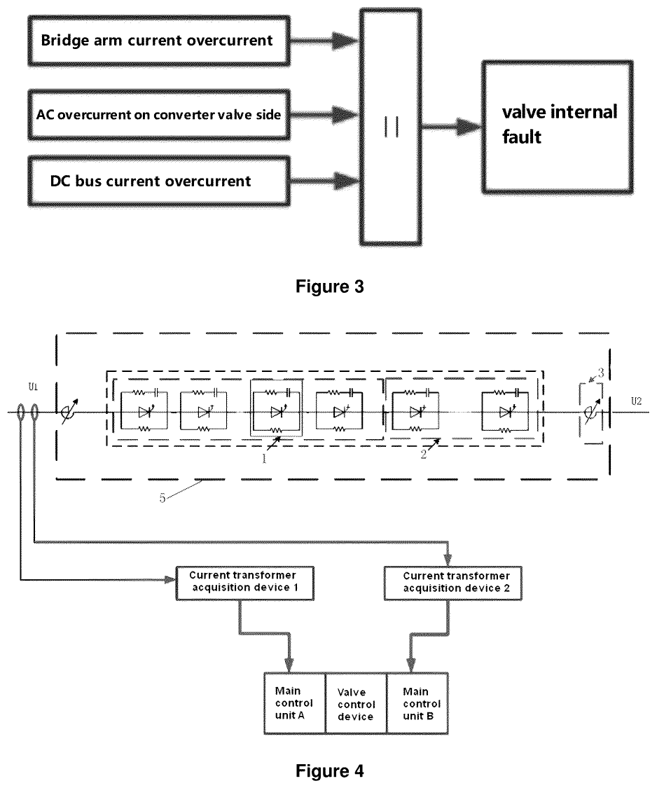

Referring to FIGS. 1-5, a current transformer acquisition device is installed on each arm of the current transformer configuration topology to measure the converter arm current. The current transformer acquisition device is connected to both a valve control device and a pole control device. The valve control device measures the DC bus current and the AC current on the converter transformer valve side to make active shutdown judgments. The pole control device simultaneously measures the arm current, the DC bus current, and the AC current on the converter transformer valve side to make valve internal fault judgments.

The active shutdown strategy requires measuring the converter arm current, and a current measuring transformer is installed on each arm. The active shutdown strategy also measures the DC bus current and the AC current on the converter transformer valve side. The valve fault is also measured simultaneously with the bridge arm current, DC bus current, and AC current on the converter transformer valve side.

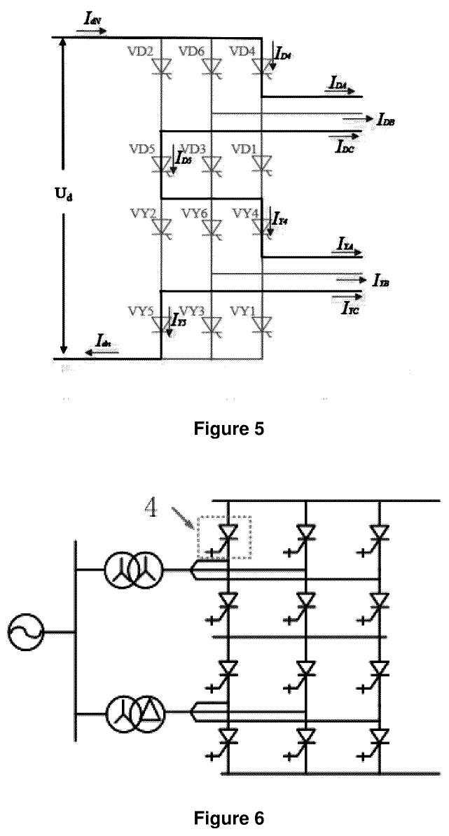

The valve control system acquires AC current and DC bus current values in real time. Based on the CP signal and bushing current, the valve control system calculates the bridge arm current, and the inflow and outflow currents of the Y and D valves. Taking valves D4 and D5 as conducting as an example, when there is no additional path or no conducting loop within the valve, the bridge arm current ID4 equals the bushing current IDA, and the bridge arm current ID5 equals IDC. The correspondence between the converter valve bridge arm current, the DAY valve inflow and outflow currents, and the bushing current is shown in FIG. 5. The correspondence between the CP signal, bushing current value, and valve inflow and outflow currents is shown in the Table 1 below (IDA is the bushing current of phase A of valve D).

TABLE 1

| Num- | | | | Corresponce relation | | | | | |
|---|---|---|---|---|---|---|---|---|---|
| ber | Status | CP signals | Converter valve status | IDA | IDB | IDC | IYA | IYB | IYC |
| 1 | 1 | VY4, VD4, VY5, VD5 | Commutation to AC phase | ID4 | Minus ID3 | Minus ID5 | IY4 | Minus IY3 | Minus IY5 |
| 2 | 2 | VD4, VY5, VD5, VY6 | AC to BC commutation (Y-bridge) | ID4 | Minus ID3 | Minus ID5 | IY4 | IY6 | Minus IY5 |
| | 3 | VY4, VY5, VD5, VD6 | AC to BC commutation (D-bridge) | ID4 | ID6 | Minus ID5 | IY4 | Minus IY3 | Minus IY5 |
| 3 | 4 | VY5, VD5, VD6, VY6 | AC phase switched to BC | ID4 | ID6 | Minus ID5 | IY4 | IY6 | Minus IY5 |
| | | | phase (Y- bridge first) | | | | | | |
| | | | AC phase switched to BC | | | | | | |
| | | | phase (D-bridge first) | | | | | | |
| 4 | 5 | VD5, VD6, VY6, VY1 | BC to BA commutation (Y-bridge) | ID4 | ID6 | Minus ID5 | Minus IY1 | IY6 | Minus IY5 |
| | 6 | VY5, VD6, VY6, VD1 | BC to BA commutation (D-bridge) | Minus ID1 | ID6 | Minus ID5 | IY4 | IY6 | Minus IY5 |
| 5 | 7 | VY6, VD6, VY1, VD1 | BC phase switched to BA phase | Minus ID1 | ID6 | Minus ID5 | Minus IY1 | IY6 | Minus IY5 |
| 6 | 8 | VD6, VY1, VD1, VY2 | BC to CA commutation (Y-bridge) | Minus ID1 | ID6 | Minus ID5 | Minus IY1 | IY6 | IY2 |
| | 9 | VY6, VY1, VD1, VD2 | BC to CA commutation (D-bridge) | Minus ID1 | ID6 | ID2 | Minus IY1 | IY6 | Minus IY5 |
| 7 | 10 | VY1, VD1, VY2, VD2 | Commutation to CA phase | Minus ID1 | ID6 | ID2 | Minus IY1 | IY6 | IY2 |
| 8 | 11 | VD1, VY2, VD2, VY3 | CA to CB commutation (Y-bridge) | Minus ID1 | ID6 | ID2 | Minus IY1 | Minus IY3 | IY2 |
| | 12 | VY1, VY2, VD2, VD3 | CA to CB commutation (D-bridge) | Minus ID1 | Minus ID3 | ID2 | Minus IY1 | IY6 | IY2 |
| 9 | 13 | VY2, VD2, VY3, VD3 | Commutation to CB phase | Minus ID1 | Minus ID3 | ID2 | Minus IY1 | Minus IY3 | IY2 |
| 10 | 14 | VD2, VY3, VD3, VY4 | CB to AB commutation (Y-bridge) | Minus ID1 | Minus ID3 | ID2 | IY4 | Minus IY3 | IY2 |
| | 15 | VY2, VY3, VD3, VD4 | CB to AB commutation (D-bridge) | ID4 | Minus ID3 | ID2 | Minus IY1 | Minus IY3 | IY2 |
| 11 | 16 | VY3, VD3, VY4, VD4 | Commutation to AB phase | ID4 | Minus ID3 | ID2 | IY4 | Minus IY3 | IY2 |
| 12 | 17 | VD3, VY4, VD4, VY5 | AB to AC commutation (Y-bridge) | ID4 | Minus ID3 | ID2 | IY4 | Minus IY3 | Minus IY5 |
| | 18 | VY3, VY4, VD4, VD5 | AB to AC commutation (D-bridge) | ID4 | Minus ID3 | Minus ID5 | IY4 | Minus IY3 | IY2 |

The valve controller monitors the valve internal current value according to a preset strategy. When the valve controller determines one of the following conditions, it considers that a fault has occurred in the converter valve and should exit the active shutdown function.

TABLE 2

| Number | Fault status | Faut criteria | Values |
|---|---|---|---|
| 1 | The difference between the | An additional electrical path | 0.1pu |
| | maximum value of the DC output | appears inside the valve, or | |
| | current and the maximum value of | the existing electrical path is | |
| | the Y-bridge AC current is greater | not connected. | |
| | than the set value. | | |
| 2 | The difference between the | | |
| | maximum value of the DC input | | |
| | current and the maximum value of | | |
| | the D-bridge AC current is greater | | |
| | than the set value. | | |
| 3 | The difference between the | | |
| | maximum AC current of the D- | | |
| | bridge and the maximum AC | | |
| | current of the Y-bridge is greater | | |
| | than the set value. | | |
| 4 | When the CP signal ends, the | Bridge arm triggered abnormal | 0.5ldN |
| | bridge arm current is less than the | | |
| | comparison value. | | |
| 5 | Bridge arm current exceeds set value | Commutation bridge arm overcurrent | 5.35kA |

The criteria for the active shutdown strategy mainly include two aspects: one is that the judgment of normal zero-crossing shutdown of the bridge arm during normal operation; the other is that if commutation failure occurs and the bridge arm current does not cross zero, the active shutdown strategy will be executed.

To increase the reliability of data acquisition, each current measurement point adopts a dual-redundancy method, as shown in FIG. 4. The data collected by the current transformer is input into current transformer acquisition device 1 and current transformer acquisition device 2 respectively, and then input into main control unit A and main control unit B through the data acquisition device, thereby realizing the valve control device's data acquisition of dual-redundant channels.

Finally, it should be noted that the above embodiments are only used to illustrate the technical solutions of the present disclosure and not to limit them; although the present disclosure has been described in detail with reference to preferred embodiments, those skilled in the art should understand that modifications can still be made to the specific implementation of the present disclosure or equivalent substitutions can be made to some technical features without departing from the spirit of the technical solutions of the present disclosure, and all such modifications and substitutions should be covered within the scope of the technical solutions claimed in the present disclosure.

1. A method for measuring current in an HCC converter unit, comprising:
setting a current transformer acquisition device on each arm of a current transformer configuration topology to measure a converter arm current;
the current transformer acquisition device connecting to both a valve control device and a polarization control device; the valve control device measuring a DC bus current and an AC current on a converter transformer valve side to determine active shutdown;
the polarization control device measuring simultaneously a bridge arm current, a DC bus current, and an AC current on the converter transformer valve side to determine internal valve faults.

2. The method of claim 1, further comprising more than one current transformer acquisition device.

3. The method of claim 1, wherein the polarization control device includes more than one main control unit.

4. The method of claim 1, wherein the valve control device calculates a bridge arm current value, an inflow current and outflow value of the Y valve and D valve based on a CP signal and a bushing current value.

5. The method of claim 1, wherein an active shutdown judgment includes two criteria: one is that a judgment of normal zero-crossing shutdown of the bridge arm during normal operation; the other is that the active shutdown is executed when commutation failure occurs and the bridge arm current does not cross zero.

6. The method of claim 1, wherein conditions for judging the valve internal fault include overcurrent in the bridge arm, AC overcurrent on the converter transformer valve side, and DC bus overcurrent.
